(19) United States
(12) Patent Application Publication
(10) Pub. No.: US 2019/0312084 A1
(43) Pub. Date: Oct. 10, 2019

(54) LIGHT EMITTING DIODE APPARATUS AND MANUFACTURING METHOD THEREOF

(71) Applicant: SAMSUNG ELECTRONICS CO., LTD., Suwon-si (KR)

(72) Inventor: Jinhee KANG, Suwon-si (KR)

(73) Assignee: SAMSUNG ELECTRONICS CO., LTD., Suwon-si (KR)

(21) Appl. No.: 16/289,101

(22) Filed: Feb. 28, 2019

(30) Foreign Application Priority Data
Apr. 10, 2018 (KR) 10-2018-0041761

(51) Int. Cl. H01L 27/15; H01L 33/46; H01L 33/24; H01L 33/38; H01L 33/62; H01L 33/50; H01L 33/54; H01L 33/06

(52) U.S. Cl. CPC H01L 27/156; H01L 33/32; H01L 33/24; H01L 33/385; H01L 33/62; H01L 33/505; H01L 33/54; H01L 33/502; H01L 33/06; H01L 2933/0016; H01L 2933/0025; H01L 2933/0041; H01L 2933/005; H01L 2933/0066; H01L 33/46

(57) ABSTRACT

A method of manufacturing a light emitting diode is provided. The method of manufacturing a light emitting diode includes the steps of forming a mask layer including a plurality of grooves on one side of a substrate, forming an insulating layer on the other side of the substrate, preparing a plurality of sub pixel areas on the substrate on which the mask layer has been formed, forming a nanostructure in at least one groove included in each of the plurality of sub pixel areas, forming a first electrode on the mask layer and the nanostructure corresponding to each of the plurality of sub pixel areas, etching an area of the insulating layer corresponding to each of the plurality of sub pixel areas and forming a first semiconductor layer and a second electrode, forming a metallic substance in a via hole which is provided between the plurality of sub pixel areas and connects the one side and the other side of the substrate, and forming a second semiconductor layer and a third electrode in an area corresponding to the via hole on the other side of the substrate.

### CROSS-REFERENCE TO RELATED APPLICATION(S)

This application is based on and claims priority under 35 U.S.C. § 119(a) of a Korean Patent Application No. 10-2018-0041761, filed on Apr. 10, 2018, in the Korean Intellectual Property Office, the disclosure of which is incorporated by reference herein in its entirety.

### BACKGROUND

### 1. Field

The disclosure relates to a light emitting diode and a manufacturing method thereof, and more particularly, to a light emitting diode including nanostructures and a manufacturing method thereof.

### 2. Description of Related Art

Spurred by the development of electronic technologies, various types of electronic products are being developed and distributed. As uses of display devices have increased, users' needs for more various functions have also increased. Following this trend, manufacturing companies of display devices are exerting more effort to meet the users' needs, and as a result, products equipped with new functions that did not exist before are appearing one after another.

In particular, as uses of LED display devices for advertisements or billboards have increased, various technologies for driving LED display devices effectively have also emerged.

In conventional LED display devices, there was a problem that in the sub pixels of red (R), green (G), blue (B) and white (W), light in an unexpected color was emitted due to interference between adjacent sub pixels. Also, in the conventional LED display devices, electrodes were arranged such that each of the sub pixels can independently emit light under control, and due to this, there was a problem that manufacturing processes became complex, and the manufacturing cost was high.

### SUMMARY

The disclosure addresses the aforementioned needs. Accordingly, the disclosure is aimed at providing a light emitting diode which blocks transmission of light among the R, G, B and W sub pixels, and a manufacturing method thereof

A method of manufacturing a light emitting diode according to an embodiment of the disclosure for achieving the aforementioned purpose may include the steps of forming a mask layer including a plurality of grooves on one side of a substrate, forming an insulating layer on the other side of the substrate, preparing a plurality of sub pixel areas on the substrate on which the mask layer has been formed, forming a nanostructure in at least one groove included in each of the plurality of sub pixel areas, forming a first electrode on the mask layer and the nanostructure corresponding to each of the plurality of sub pixel areas, etching an area of the insulating layer corresponding to each of the plurality of sub pixel areas and forming a first semiconductor layer and a second electrode, forming a metallic substance in a via hole which is provided between the plurality of sub pixel areas and connects the one side and the other side of the substrate, and forming a second semiconductor layer and a third electrode in an area corresponding to the via hole on the other side of the substrate.

Here, the nanostructure may be a structure where a p-type semiconductor layer, an active layer and an n-type semiconductor layer are laminated, the first electrode formed on the nanostructure may be an n-type electrode, the first semiconductor layer may be a p-type semiconductor layer, the second electrode may be a p-type electrode, the second semiconductor layer may be an n-type semiconductor layer, and the third electrode may be an n-type electrode.

Meanwhile, in the step of forming the metallic substance in the via hole, the metallic substance may be formed such that the metallic substance contacts the first electrode formed on the mask layer.

Also, the method of manufacturing a light emitting diode may include the step of forming, on the substrate, a first partition wall of a predetermined height in the area of the substrate between the plurality of sub pixel areas, and the first partition wall may block transmission of light emitted from at least one nanostructure provided in a sub pixel area among the plurality of sub pixel areas to another sub pixel area.

In addition, the method of manufacturing a light emitting diode may include the step of forming, on the substrate, a second partition wall of a predetermined height enclosing an outer rim of the plurality of sub pixel areas, and the second partition wall may block transmission of light emitted from another light emitting diode to the light emitting diode.

Here, the method of manufacturing a light emitting diode may include the step of forming a fluorescent layer in a different color in each of the plurality of sub pixel areas, and the fluorescent layer in a different color may convert light emitted from the nanostructure provided in each of the plurality of sub pixel areas into any one of red (R), green (G), blue (B) and white (W).

Meanwhile, the step of forming a fluorescent layer may include the step of forming quantum dots inside the plurality of sub pixel areas divided by the first and second partition walls.

Also, the step of forming a fluorescent layer may include the step of, after forming the quantum dots, forming an encapsulant on top of the quantum dots, and may further include the step of forming encapsulation glass (EG) on top of the first and second partition walls and the encapsulant.

Further, the step of forming a fluorescent layer may include the steps of forming a glass layer supported by the first and second partition walls on top of the plurality of sub pixel areas, and forming a quantum dot layer in an area corresponding to each of the plurality of sub pixel areas on top of the glass layer.

In addition, the plurality of sub pixel areas may include first to fourth sub pixel areas arranged in the form of a 2*2 matrix, and in the step of forming the metallic substance in the via hole, a via hole of a predetermined size may be formed in a center portion of the plurality of sub pixel areas contacted by all of the first to fourth sub pixel areas.

Meanwhile, a light emitting diode according to an embodiment of the disclosure may include a substrate, at least one nanostructure formed in an area of each of the plurality of sub pixel areas provided on one side of the substrate, a first insulating layer formed in the remaining area on the one side of the substrate, a first electrode formed on the first insulating layer and the nanostructure, a first semiconductor layer formed in an area on the other side of the substrate, a second electrode formed on the first semiconductor layer, a second insulating layer formed in the remaining area on the other side of the substrate, a metallic substance which is provided between the plurality of sub pixel areas and connects the one side and the other side of the substrate, a second semiconductor layer formed in an area corresponding to the metallic substance on the other side of the substrate, and a third electrode formed on the second semiconductor layer.

Here, the nanostructure may be a structure where a p-type semiconductor layer, an active layer and an n-type semiconductor layer are laminated, and the first electrode formed on the nanostructure may be an n-type electrode, the first semiconductor layer may be a p-type semiconductor layer, the second electrode may be a p-type electrode, the second semiconductor layer may be an n-type semiconductor layer, and the third electrode may be an n-type electrode.

In addition, the metallic substance may be formed such that the metallic substance contacts the first electrode formed on the first insulating layer.

Further, the light emitting diode according to an embodiment of the disclosure may include a first partition wall of a predetermined height formed in the area of the substrate between the plurality of sub pixel areas, and the first partition wall may block transmission of light emitted from at least one nanostructure provided in a sub pixel area among the plurality of sub pixel areas to another sub pixel area.

Also, the light emitting diode according to an embodiment of the disclosure may include a second partition wall of a predetermined height enclosing the outer rim of the plurality of sub pixel areas, and the second partition wall may block transmission of light emitted from another light emitting diode to the light emitting diode.

Here, the light emitting diode according to an embodiment of the disclosure may include a fluorescent layer formed in each of the plurality of sub pixel areas, and the fluorescent layer may convert light emitted from the nanostructure provided in each of the plurality of sub pixel areas into any one of R, G, B and W.

Also, the fluorescent layer may be implemented as quantum dots formed inside the plurality of sub pixel areas divided by the first and second partition walls.

Further, the fluorescent layer may further include an encapsulant formed on top of the quantum dots, and EG formed on top of the first and second partition walls and the encapsulant.

In addition, the light emitting diode according to an embodiment of the disclosure may include a glass layer supported by the first and second partition walls on top of the plurality of sub pixel areas, and the fluorescent layer may be implemented as a quantum dot layer formed in an area corresponding to each of the plurality of sub pixel areas on top of the glass layer.

Meanwhile, the plurality of sub pixel areas may include first to fourth sub pixel areas arranged in the form of a 2*2 matrix, and the metallic substance may be formed in a center portion of the plurality of sub pixel areas contacted by all of the first to fourth sub pixel areas.

According to the various embodiments of the disclosure as described above, emission of light in an unexpected color can be prevented, and a pixel structure which enables independent control through combination of three colors (Red/Green/Blue) of a light emitting diode and electric insulation can be achieved. In addition, sub pixels in three colors in a single pixel can be efficiently constituted, and fairness in formation of electrodes thereof can be secured. Thus, when a display device is manufactured by using the method according to the various embodiments of the disclosure, time and cost for manufacturing a light emitting diode can be reduced.

### BRIEF DESCRIPTION OF THE DRAWINGS

FIG. 1 is a diagram for illustrating a light emitting diode according to an embodiment of the disclosure;

FIG. 2 is a diagram for illustrating a method of manufacturing a light emitting diode according to an embodiment of the disclosure;

FIG. 3 is a diagram for illustrating a method of manufacturing a light emitting diode according to an embodiment of the disclosure;

FIG. 4 is a diagram for illustrating a method of manufacturing a light emitting diode according to an embodiment of the disclosure;

FIG. 5 is a diagram for illustrating a method of manufacturing a light emitting diode according to an embodiment of the disclosure;

FIG. 6 is a diagram for illustrating a method of manufacturing a light emitting diode according to an embodiment of the disclosure;

FIG. 7 is a diagram for illustrating a method of manufacturing a light emitting diode according to an embodiment of the disclosure;

FIG. 8 is a bottom view for illustrating a light emitting diode according to another embodiment of the disclosure;

FIG. 9 is a plan view for illustrating a light emitting diode according to an embodiment of the disclosure;

FIG. 10 is a flow chart for illustrating a method of manufacturing a light emitting diode according to an embodiment of the disclosure.

### DETAILED DESCRIPTION

Hereinafter, the terms used in this specification will be described briefly, and also, the disclosure will be described in detail.

As terms used in the embodiments of the disclosure, general terms that are currently used widely were selected as far as possible, in consideration of the functions described in the disclosure. However, the terms may vary depending on the intention of those skilled in the art, previous court decisions or emergence of new technologies. Also, in particular cases, there may be terms that were arbitrarily designated by the applicant, and in such cases, the meaning of the terms will be described in detail in the relevant descriptions in the disclosure. Thus, the terms used in the disclosure should be defined based on the meaning of the terms and the overall content of the disclosure, but not just based on the names of the terms.

Further, various modifications may be made to the embodiments of the disclosure, and there may be various types of embodiments. Accordingly, specific embodiments will be illustrated in drawings, and the embodiments will be described in detail in the detailed description. However, it should be noted that the various embodiments are not for limiting the scope of the disclosure to a specific embodiment, but they should be interpreted to include all modifications, equivalents or alternatives of the embodiments included in the ideas and the technical scopes disclosed herein. Meanwhile, in case it is determined that in describing the embodiments, detailed explanation of related known technologies may unnecessarily confuse the gist of the disclosure, the detailed explanation will be omitted.

In addition, the expressions “first,” “second” and the like used in the disclosure may be used to describe various elements, but the expressions are not intended to limit the elements. Such expressions are used only to distinguish one element from another element.

Also, singular expressions may be interpreted to include plural expressions, unless defined obviously differently in the context. In this specification, terms such as “include” and “consist of” should be construed as designating that there are such characteristics, numbers, steps, operations, elements, components or a combination thereof in the specification, but not as excluding in advance the existence or possibility of adding one or more of other characteristics, numbers, steps, operations, elements, components or a combination thereof.

Meanwhile, “a module” or “a part” in the disclosure perform at least one function or operation, and these elements may be implemented as hardware or software, or as a combination of hardware and software. Further, a plurality of “modules” or “parts” may be integrated into at least one module and implemented as at least one processor (not shown), except “modules” or “parts” that need to be implemented as specific hardware.

Hereinafter, the embodiments of the disclosure will be described in detail with reference to the accompanying drawings, such that those having ordinary skill in the art to which the disclosure belongs can easily carry out the disclosure. However, it should be noted that the disclosure may be implemented in various different forms, and is not limited to the embodiments described herein. Also, in the drawings, parts that are not related to explanation were omitted, for explaining the disclosure clearly, and throughout the specification, similar components were designated by similar reference numerals.

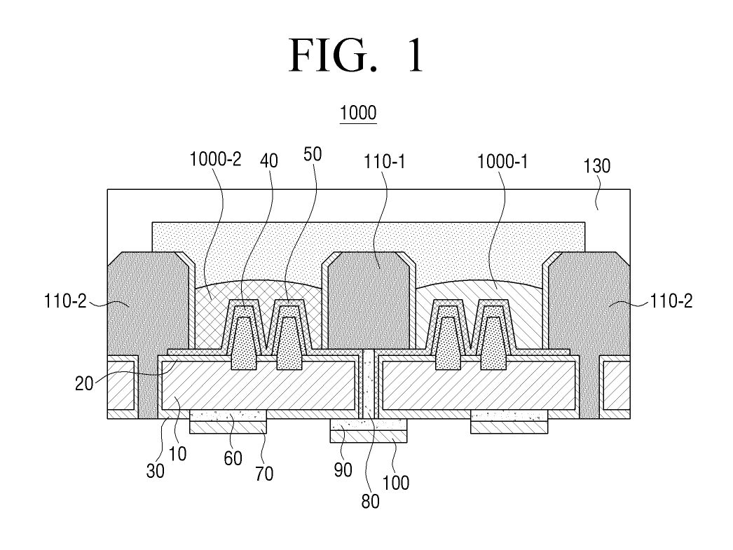

FIG. 1 is a diagram for illustrating a light emitting diode according to an embodiment of the disclosure.

According to FIG. 1, a light emitting diode (1000) includes a substrate (10), a first insulating layer (20), a second insulating layer (30), a nanostructure (40), a first electrode (50), a first semiconductor layer (60), a second electrode (70), a metallic substance (80), a second semiconductor layer (90) and a third electrode (100).

The substrate (10) may be a substrate for the growth of a semiconductor that can grow a semiconductor substance on its top surface. To be specific, the substrate (10) may be a sapphire substrate, a silicon (Si) substrate, a zinc oxide (ZnO) substrate, a nitride semiconductor substrate or a template substrate on which at least one of GaN, InGaN, AlGaN or AlInGaN is laminated. As an example, the substrate (10) may be a sapphire substrate, and may grow a nitride layer having a hexagonal crystal system. However, the substrate is not limited thereto, and it may be a metal substrate including a metallic substance such as Cu, Cr, Ni, Ag, Au, Mo, Pd, W or Al. Hereinafter, for the convenience of description, the disclosure will be described based on an assumption of a case where the substrate (10) consists of silicon wafer (Si-Wafer).

Meanwhile, according to an embodiment of the disclosure, a light extraction structure may be formed on the surface of the substrate (10), and light efficiency may thereby be enhanced. Here, the light extraction structure may include a concave-convex pattern having at least two periods that are different from each other.

The first insulating layer (20) may be formed on one side of the substrate (10). The first insulating layer (20) according to an embodiment of the disclosure may refer to a mask layer. The first insulating layer (20) may include silicon oxides or silicon nitrides, and may include, for example, at least one of SiOₓ, SiOₓN_{y}, SiₓN_{y}, Al₂O₃, TiN, AlN, ZrO, TiAlN or TiSiN. In particular, the first insulating layer (20) may be a distributed Bragg reflector (DBR) layer or an omni-directional reflector (ODR) layer. In this case, the first insulating layer (20) may have a structure where layers having different refractive indices are arranged alternatingly. However, the insulating layer (20) is not limited thereto, and it may be a single layer including at least one of SiO, SiON, SiN, Al₂O₃, TiN, AlN, ZrO, TiAlN or TiSiN.

The first insulating layer (20) according to an embodiment of the disclosure may include a plurality of grooves that expose some portions of the substrate (10). Here, according to the sizes of the plurality of grooves, the diameter, length, location and growth condition of the nanostructure (40) that will be described below may be determined. As an example, each of the plurality of grooves may have various forms, such as a rectangle, a circle and the like.

Meanwhile, the second insulating layer (30) may be formed on the other side of the substrate (10). As will be described below, the second insulating layer (30) may be formed on the other side of the substrate (10) for electrically insulating the second electrode (70) and the third electrode (100) that are electrically connected to the first semiconductor (60). The second insulating layer (30) may include polyimide, SiNₓ, etc., but is not limited thereto, and the layer may be formed in various types of substances that enable electrical insulation.

The nanostructure (40) may be formed in each of the plurality of grooves. Meanwhile, in the light emitting diode (1000) according to an embodiment of the disclosure, a plurality of sub pixel areas may be formed on one side of the substrate on which the first insulating layer (20) has been formed.

As an example, the plurality of sub pixel areas may include first to fourth sub pixel areas arranged in the form of a 2*2 matrix. However, the disclosure is not limited thereto, and the sub pixel areas can include a plurality of sub pixel areas arranged in various types of patterns, such as pentiles and stripes.

The nanostructure (40) may be formed in at least one groove included in each of the plurality of sub pixel areas. Here, the nanostructure (40) may include a plurality of nano-shaped p-type semiconductors that were grown and formed from the substrate (10), a plurality of active layers formed on each of the plurality of p-type semiconductors, and a plurality of n-type semiconductors formed on each of the plurality of active layers. As an example, the nanostructure (40) may have a core-shell structure including p-type semiconductors grown from the substrate (10) exposed by a plurality of grooves on the first insulating layer (20), active layers that are sequentially formed on the surfaces of the p-type semiconductors, and n-type semiconductors that are sequentially formed on the surfaces of the active layers.

Here, the p-type semiconductors, active layers, and n-type semiconductors included in the nanostructure (40) are not necessarily formed in a core-shell structure, but they can be formed in a laminated structure where the p-type semiconductors, active layers, and n-type semiconductors are sequentially formed. Also, the nanostructure (40) may be in the form of a pyramid, a column, or a circle. As the nanostructure (40) has a three-dimensional shape, its light emitting surface area relatively increases compared to a conventional two-dimensional shape. Accordingly, its light extraction efficiency can be enhanced.

The light emitting diode (1000) according to an embodiment of the disclosure may include the first electrode (50) formed on the first insulating layer (20) and the nanostructure (40) corresponding to each of the plurality of sub pixel areas. The first electrode (50) may be electrically connected to the n-type semiconductor layer provided on the nanostructure (40). As the first electrode (50) is electrically connected to the n-type semiconductor layer, electric charges may be introduced into the n-type semiconductor layer. The electric charges introduced into the n-type semiconductor layer according to an embodiment of the disclosure may be recombined with holes as will be described below, and the light emitting diode (1000) may emit light.

After the second insulating layer (30) is formed on the other side of the substrate (10) according to an embodiment of the disclosure, an area of the second insulating layer (30) may be etched, and the first semiconductor layer (60) may be formed in the etched area. For example, an area of the second insulating layer (30) may be etched so that an area on the other side of the substrate (10) can be exposed. An area that is exposed by etching may have a depth of approximately 1-3 μm, and in the area, the first semiconductor layer (60) may be formed. Here, the first semiconductor layer (60) may be a p-type semiconductor layer.

The second electrode (70) may be formed on the first semiconductor layer (60). The second electrode (70) is electrically connected to the first semiconductor layer (60). As an example, the second electrode (70) may be indium tin oxide (ITO), aluminium zinc oxide (AZO), indium zinc oxide (IZO), ZnO, GZO(ZnO:Ga), In₂O₃, SnO₂, CdO, CdSnO₄ or Ga₂O₃. The second electrode (70) may be referred to as a transparent electrode or a transparent electrode layer, but it will be uniformly referred to as the second electrode (70) below, for the convenience of description. Here, the second electrode (70) may be a p-type electrode.

As the second electrode (70) is electrically connected to the first semiconductor layer (60), holes may be introduced into the first semiconductor layer (60). As described above, the first electrode (50) is electrically connected to the n-type semiconductor layer provided on the nanostructure (40), and accordingly, electric charges are introduced into the n-type semiconductor layer. Further, as holes are introduced into the p-type semiconductor layer provided on the nanostructure (40) through the substrate (10) due to introduction of holes into the first semiconductor layer (60), the active layer located between the n-type semiconductor layer and the p-type semiconductor layer may emit light having specific energy by recombination of electrons and holes. Here, the active layer may be a layer consisting of a single substance such as InGaN, but in case the active layer is a single or multiple quantum well structure where quantum barrier layers and quantum well layers are arranged alternatingly, e.g., a nitride semiconductor, a GaN/InGaN may be used.

Meanwhile, the light emitting diode (1000) according to an embodiment of the disclosure may include the metallic substance (80) that is provided between the plurality of sub pixel areas and connects one side and the other side of the substrate (10).

As an example, after the first insulating layer (20), the second insulating layer (30), the nanostructure (40), the first electrode (50), the first semiconductor layer (50) and the second electrode (70) are formed, a via hole connecting one side and the other side of the substrate (10) may be formed, and the metallic substance (80) may be formed in the via hole.

Here, the metallic substance (80) may contact the first electrode (50) formed on one side of the substrate (10). For example, in the light emitting diode (1000), a plurality of sub pixel areas may be provided, and the first electrode (50) formed in each of the plurality of sub pixel areas and the metallic substance (80) may contact each other.

Also, the light emitting diode (1000) according to an embodiment of the disclosure may include the second semiconductor layer (90) formed in an area corresponding to the metallic substance (80) on the other side of the substrate (10), and may also include the third electrode (100) formed on the second semiconductor layer (90). Here, electrons provided by the third electrode (100) are introduced into the metallic substance (80) through the second semiconductor layer (90), and as the metallic substance (80) contacts the first electrode (50), the electrons may be introduced into the n-type semiconductor layer provided on the nanostructure (40). As the electrons introduced into the n-type semiconductor layer and the holes introduced into the p-type semiconductor layer provided on the nanostructure through the second electrode (70) are recombined, light having specific energy may be emitted. Here, the metallic substance (80) may be a metallic substance such as Cu, Cr, Ni, Ag, Au, Mo, Pd, W or Al. However, the metallic substance (80) is not limited thereto, and the substance may be implemented as various types of substances that can move electrons from the second semiconductor layer (90) to the first electrode (50).

Referring to FIG. 1, each of the plurality of sub pixel areas provided on the light emitting diode (1000) may include the first semiconductor layer (60) and the second electrode (70). Meanwhile, the light emitting diode (1000) includes the second semiconductor layer (90) and the third electrode (100) contacting the metallic substance (80), and the metallic substance (80) contacts the first electrode provided in each of the plurality of sub pixel areas, and thus the electrons introduced by the third electrode (100) may be provided to each of the plurality of sub pixel areas.

As an example, the light emitting diode (1000) including first to fourth sub pixel areas may include the first semiconductor layer (60) and the second electrode (70) provided in each of the first to fourth sub pixel areas, and may also include one second semiconductor layer (90) and one third electrode (100). Here, the second semiconductor layer (90) and the third electrode (100) may be implemented as an n-type semiconductor layer and an n-type electrode, respectively. As the electrons introduced into the n-type semiconductor layer from the n-type electrode are transmitted to the metallic substance (80), and the metallic substance (80) contacts the first electrode (50) provided in each of the first to fourth sub pixel areas, the electrons may be introduced into each of the first to fourth sub pixel areas.

In addition, the light emitting diode (1000) according to an embodiment of the disclosure may include first to fourth sub pixel areas arranged in the form of a 2*2 matrix, and the metallic substance (80) may be formed in the center portion of the plurality of sub pixel areas contacted by all of the first to fourth sub pixel areas. For example, the metallic substance (80) formed in the center portion may commonly contact the first electrode (50) formed in each of the plurality of sub pixel areas. Accordingly, the second semiconductor layer (90) and the third electrode (100) may not be formed in each of the plurality of sub pixel areas, and even if one second semiconductor layer (90) and one third electrode (100) are formed, electrons may be introduced into each of the plurality of sub pixel areas.

Further, each of the plurality of sub pixel areas according to an embodiment of the disclosure may emit light through the nanostructure (40) included in each of the sub pixel areas, and the emitted light may be converted into a specific color through first and second fluorescent layers (1000-1, 1000-2) formed inside the sub pixel areas.

Referring to FIG. 1, as light emitted from the first sub pixel area passes through the first fluorescent layer (1000-1), the light may be converted into light in a specific color corresponding to the first fluorescent layer (1000-1). Also, as light emitted from the second sub pixel area passes through the second fluorescent layer (1000-2), the light may be converted into light in a specific color corresponding to the second fluorescent layer (1000-2). Further, the fluorescent layers (1000-1, 1000-2) according to an embodiment of the disclosure are quantum dots, and may be implemented as phosphor, quantum dots, etc. formed inside the sub pixel areas.

Quantum dots are nano materials in a size of 10˜15 nm which generate light of a shorter wavelength as their particles are smaller, and generate light of a longer wavelength as their particles are bigger, and they can generate all the light in a visible light area as their particle size is adjusted. Also, quantum dots can implement all natural colors with their material itself. Further, quantum dots can easily control wavelengths of light, and thus their color gamut and brightness of light are of high quality.

For example, if a color corresponding to the first fluorescent layer (1000-1) is red (R), the first sub pixel area may emit light in R color. Meanwhile, if a color corresponding to the second fluorescent layer (1000-2) is green (G), the second sub pixel area may emit light in G color.

As another example, a case where the light emitting diode (1000) includes first to fourth sub pixel areas, and the first to fourth sub pixel areas emit different light from one another because of the fluorescent layer formed in each sub pixel area can be assumed. For example, the first to fourth sub pixel areas may emit light of red (R), green (G), blue (B) and white (W).

Here, the light emitted from a sub pixel area may be transmitted to another sub pixel area that is arranged nearby. For example, if a sub pixel area emitting light of B color, which is arranged near a sub pixel area emitting light of W color, emits light, the light emitted from the B sub pixel area may be reflected on a fluorescent layer formed on the W sub pixel area, and as a result, light of W color may be emitted. Accordingly, there is a problem that, even in a case where the B sub pixel area emits light, and the W sub pixel area does not emit light, light of both of B color and W color is emitted.

The light emitting diode (1000) according to an embodiment of the disclosure may include a first partition wall (110-1) of a predetermined height that is formed in the area of the substrate between the plurality of sub pixel areas. Here, the first partition wall (110-1) may block transmission of light emitted from at least one nanostructure (40) provided in a sub pixel area among the plurality of sub pixel areas to another sub pixel area.

For example, the first partition wall (110-1) which blocks transmission of light emitted from the B sub pixel area to another sub pixel area (e.g., a G sub pixel area, an R sub pixel area, a W sub pixel area) may be formed in the area of the substrate between the plurality of sub pixel areas. Referring to FIG. 1, the first partition wall (110-1) may be formed on one side of the substrate (10) and the metallic substance (80).

Further, the light emitting diode (1000) according to an embodiment of the disclosure may include the second partition wall (110-2) of a predetermined height enclosing the outer rim of the plurality of sub pixel areas on the substrate. Here, the second partition wall (110-2) may block transmission of light emitted from another light emitting diode to the light emitting diode (1000), and may also block transmission of light emitted from the light emitting diode (1000) to another light emitting diode. The first and second partition walls (110-1, 110-2) may be referred to as light leakage prevention films, black matrices (BMs) and walls, but for the convenience of description, they will be uniformly referred to as partition walls below.

The light emitting diode (1000) according to an embodiment of the disclosure may include a glass layer (130) supported by the first partition wall (110-1) and the second partition wall (110-2) on top of the plurality of sub pixel areas. Here, the glass layer (130) may be implemented as encapsulation glass (EG). If the fluorescent layers (1000-1, 1000-2) are implemented as organic substances, the organic substances may be oxidized due to moisture transmission and contact with air, and thus fatal reduction of life may be caused to the light emitting diode (1000). Meanwhile, the EG may be glass that is used for sealing to prevent oxidation.

Meanwhile, the light emitting diode (1000) according to an embodiment of the disclosure may include an encapsulant formed between the fluorescent layers (1000-1, 1000-2) and the glass layer (130). The encapsulant can prevent the fluorescent layers (1000-1, 1000-2) from contacting air and being oxidized.

Hereinafter, a method of manufacturing the light emitting diode (1000) will be described.

Terms such as “deposition,” “growth,” “lamination,” etc. that will be used below are used in the same meaning as formation of semiconductor material layers. Also, layers or thin films formed through the various embodiments of the disclosure may grow in a chamber for growth by using a metal-organic chemical vapor deposition (MOCVD) method or a molecular beam epitaxy (MBE) method. In addition, the layers or thin films may be formed while being deposited by various methods such as a PECVD, an APCVD, an LPCVD, a UHCVD, a PVD, an electronic beam method, a resistive heating method and the like.

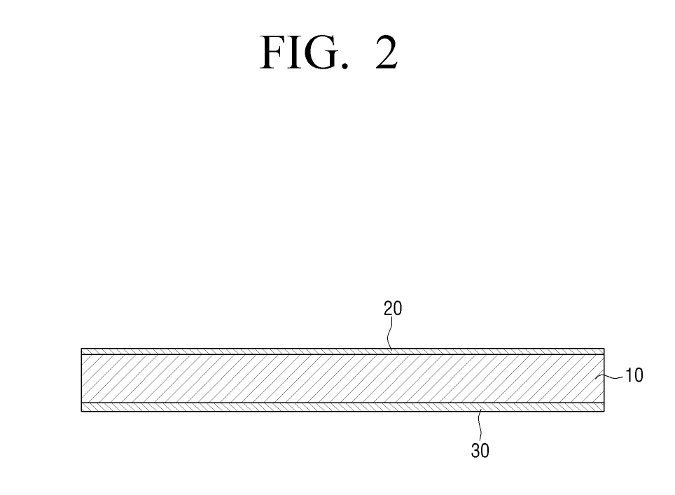

FIGS. 2 to 7 are diagrams for illustrating a method of manufacturing a light emitting diode according to an embodiment of the disclosure.

First, as illustrated in FIG. 2, the substrate (10) may be provided, and the first insulating layer (20) may be grown on one side of the substrate (10). Here, the first insulating layer (20) may also refer to a mask layer.

Then, the second insulating layer (30) may be formed on the other side of the substrate (10).

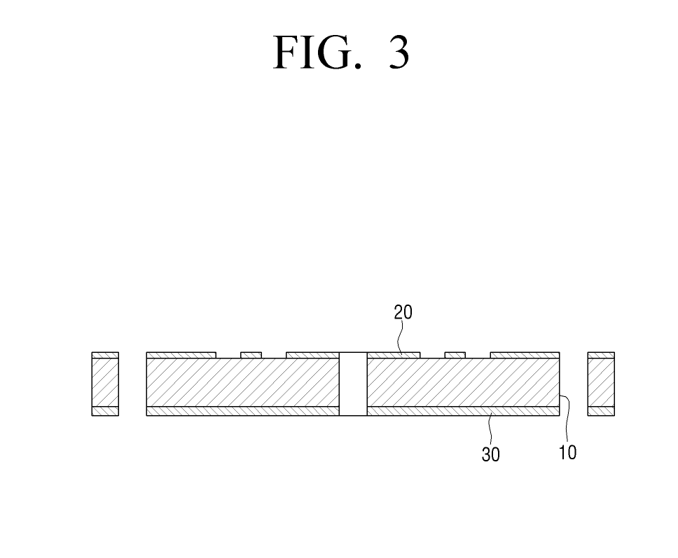

As illustrated in FIG. 3, a plurality of grooves may be formed on the first insulating layer (20) prepared in FIG. 2. For example, the first insulating layer (20) including a plurality of grooves may be formed as a mold layer including a mask pattern is formed on the first insulating layer (20), and a base layer is patterned according to the mask pattern of the mold layer. Here, the sizes of the plurality of grooves may be uniform, and the sizes of the plurality of grooves may be determined based on the size of the nanostructure (40).

Further, a plurality of sub pixel areas may be provided on the substrate (10) where a plurality of grooves have been formed. Here, the plurality of sub pixel areas may be formed in a predetermined pattern. For example, first to fourth sub pixel areas arranged in the form of a 2*2 matrix may be formed on the substrate (10). However, the sub pixel areas are not limited thereto, and a plurality of sub pixel areas arranged in various patterns can be prepared.

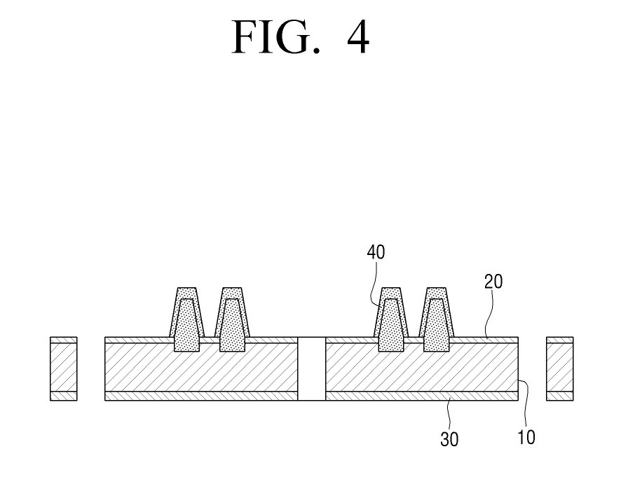

Next, referring to FIG. 4, the nanostructure (40) may be formed in at least one groove included in each of the plurality of sub pixel areas. For example, a p-type semiconductor layer may be grown and formed on one side of the substrate (10) exposed by a plurality of grooves. The p-type semiconductor layer may be formed by using a metal organic chemical vapor deposition (MOCVD) process or an MBE process. In addition, an active layer may be formed on the p-type semiconductor layer, and an n-type semiconductor layer may be formed on the active layer.

According to an embodiment of the disclosure, the p-type semiconductor, active layer, and n-type semiconductor included in the nanostructure (40) may be formed in a core-shell structure. Also, depending on the deposition method, the active layer and the n-type semiconductor may be deposited in different thicknesses from the p-type semiconductor. As another example, the nanostructure (40) can be formed in a laminated structure where a p-type semiconductor layer, an active layer, and an n-type semiconductor layer are sequentially formed, instead of a core-shell structure.

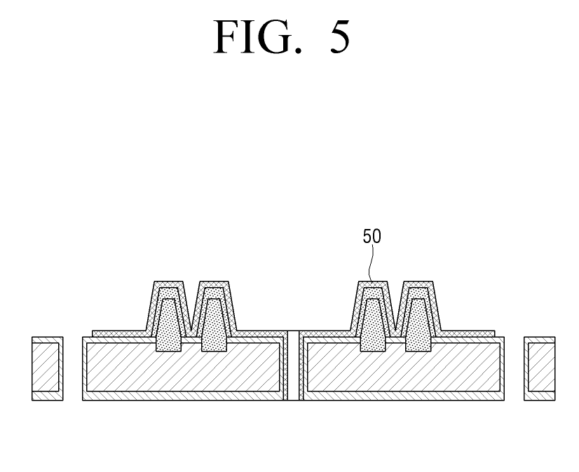

Then, as illustrated in FIG. 5, insulating layers may be formed in an outer area and the via hole of the light emitting diode (1000). If insulating layers are formed in an outer area and the via hole of the substrate (10) in order that electrons introduced from the third electrode (100) may not be introduced into the substrate (10), and the metallic substance (80) is formed in the via hole, as will be described below, electrons introduced into the metallic substance (80) may not flow into the substrate (10).

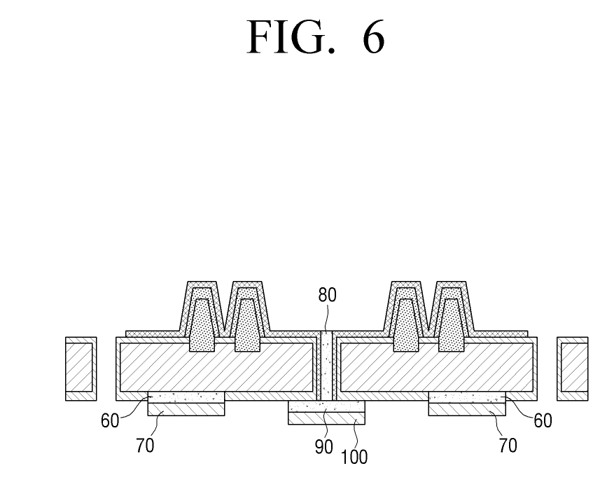

As illustrated in FIG. 6, the second insulating layer (30) provided on the other side of the substrate (10) may be etched, and an area for forming the first semiconductor layer (60) and the second electrode (70) may thereby be provided. For example, the second insulating layer (30) formed on the other side of the substrate (10) may be etched in a mesa structure. According to an embodiment of the disclosure, the second insulating layer (30) may be etched only to a predetermined depth, and as a result, a portion of the second insulating layer (30) may remain. As an example, for a patterning process, various processes such as a photolithography process and an imprinting process may be used. Meanwhile, for an etching process, processes such as wet etching using chemical products or plasma etching using reactive gases, dry etching like reactive ion etching (RIE) using an ion bombardment effect, etc., or laser ablation using laser may be used.

Here, an etching area may be formed in each of the plurality of sub pixel areas. In each of the first to fourth sub pixel areas, an area of the first insulation layer (20) may be etched so that the top portion of the other side of the substrate (10) is exposed.

Meanwhile, in an etched area, the first semiconductor layer (60) and the second electrode (70) may be formed. Here, the first semiconductor layer (60) may be provided as a p-type semiconductor layer, and the second electrode (70) may be provided as a p-type electrode.

For example, when the second electrode (70) is implemented as a p-type electrode, holes may be introduced through the second electrode (70), and the holes may be introduced into the p-type semiconductor layer provided on the nanostructure (40) through the first semiconductor layer (60) and the substrate (10).

Referring to FIG. 6, the metallic substance (80) may be formed in a via hole. The metallic substance (80) may move electrons from the other side of the substrate (10) to one side, as will be described below. Also, the metallic substance (80) according to an embodiment of the disclosure may be electrically connected to the first electrode (50) provided in each of the plurality of sub pixel areas. For example, one metallic substance (80) may be formed to contact all of the first electrodes (50) included in each of the first to fourth sub pixel areas provided in the light emitting diode (1000). Electrons moved from the other side of the substrate (10) to one side by the metallic substance (80) may be introduced into the first to fourth sub pixel areas.

The light emitting diode (1000) according to an embodiment of the disclosure may include the second semiconductor layer (90) and the third electrode (100) formed in an area corresponding to the via hole. As an example, the second semiconductor layer (90) may be electrically connected to the other side of the metallic substance (80) formed in the via hole. The electrons introduced by the third electrode (100) formed on the other side of the substrate (10) may move to one side of the substrate (10) through the second semiconductor layer (90) and the metallic substance (80). Even if the second semiconductor layer (90) and the metallic substance (80) are not provided in each of the plurality of sub pixel areas, the electrons introduced by the third electrode (100) may be introduced into each of the plurality of sub pixel areas through the metallic substance (80) electrically connected to the plurality of sub pixel areas. Here, the second semiconductor layer (90) may be implemented as an n-type semiconductor layer, and the third electrode (100) may be implemented as an n-type electrode. However, the disclosure is not limited thereto, and an n-type semiconductor layer and an n-type electrode can be formed as a p-type semiconductor layer and a p-type electrode, and a p-type semiconductor layer and a p-type electrode can be formed as an n-type semiconductor layer and an n-type electrode. That is, according to another embodiment of the disclosure, the types of a semiconductor layer and an electrode may be formed in their reverse types.

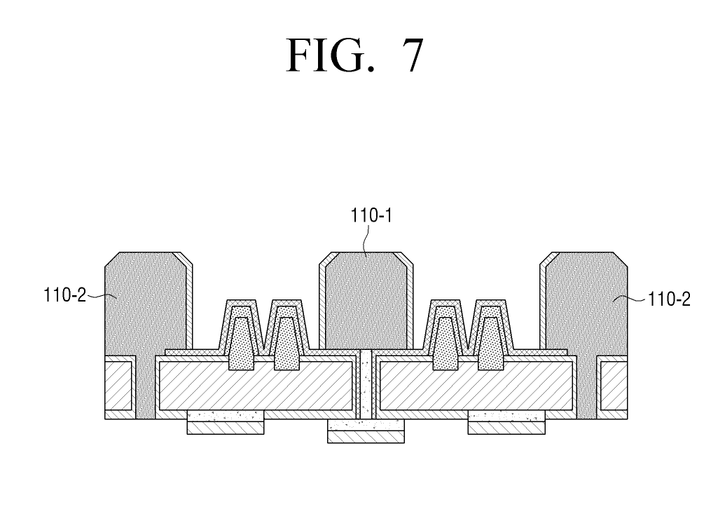

Referring to FIG. 7, the light emitting diode (1000) according to an embodiment of the disclosure may include a partition wall. The partition wall may be formed of a material that is identical or similar to those of the first and second insulating layers (20, 30). For example, the partition wall may be an insulating material, and may be one or more of inorganic insulating materials such as silicon dioxide (SiO₂), silicon nitride (Si₃N₄), aluminium oxide (Al₂O₃), hafnium oxide (HfO₂), yttrium oxide (Y₂O₃) and titanium dioxide (TiO₂), and various types of transparent polymer insulating materials. Also, the partition wall may be formed by any one of a chemical deposition method, an atomic layer deposition method, a vacuum deposition method, an e-beam deposition method and a spin coating method. However, the disclosure is not limited thereto, and the partition wall can be implemented as various materials, and can also be implemented by various methods.

Meanwhile, the first partition wall (110-1) according to an embodiment of the disclosure may be formed in a predetermined height between the plurality of sub pixel areas provided on the light emitting diode (1000).

Here, the first partition wall (110-1) may block transmission of light emitted from at least one nanostructure (40) provided in a sub pixel area among the plurality of sub pixel areas to another sub pixel area.

For example, if a B sub pixel that is arranged near a W sub pixel emits light, the light emitted from the B sub pixel is reflected on the fluorescent layer (1000-1) included in the W sub pixel, and as a result, white light may unexpectedly be emitted. Also, the first partition wall (110-1) according to an embodiment of the disclosure may prevent light emitted from a sub pixel from being reflected on the fluorescent layer (1000-1) of a nearby sub pixel.

Meanwhile, the second partition wall (110-2) according to an embodiment of the disclosure may be formed to enclose the outer rim of the light emitting diode (1000). Also, the second partition wall (110-2) may be formed in a predetermined height. Here, the second partition wall (110-2) may be formed in the same height as the first partition wall (110-1).

Further, the second partition wall (110-2) may block transmission of light emitted from another light emitting diode to the light emitting diode (1000), and it may also block transmission of light emitted from the light emitting diode (1000) to another light emitting diode.

The first and second partition walls (110-1, 110-2) according to an embodiment of the disclosure may be used as supports and blocking films. For example, when the first and second partition walls (110-1, 110-2) are formed, the plurality of sub pixel areas may be implemented in separated shapes. When the fluorescent layer (1000-1) is formed in a sub pixel area, the fluorescent layer (1000-1) may not flow into a nearby sub pixel area because of the partition wall. Also, the encapsulant that blocks contact between the fluorescent layer (1000-1) and air, and prevents oxidation may not flow into a nearby sub pixel area because of the partition wall.

Referring to FIG. 1, in the light emitting diode (1000), encapsulation glass (EG) may be provided on top of the encapsulant. Here, the EG may be formed on top of the first and second partition walls (110-1, 110-2) and the encapsulant, as the first and second partition walls (110-1, 110-2) are used as supports.

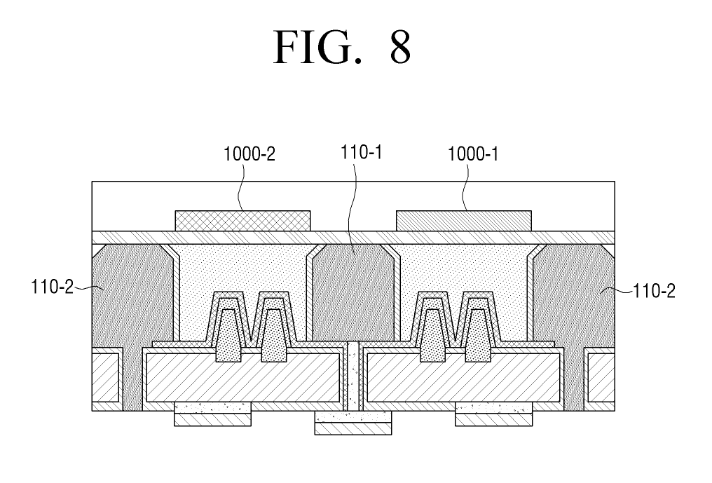

FIG. 8 is a bottom view for illustrating a light emitting diode according to another embodiment of the disclosure.

Referring to FIG. 8, as the first and second partition walls (110-1, 110-2) are formed, the inner spaces of the plurality of sub pixel areas formed may be filed with an encapsulant. However, the disclosure is not limited thereto, and the inner spaces can be in a vacuum state.

In the manufacturing method according to an embodiment of the disclosure, when the first and second partition walls (110-1, 110-2) are formed, a glass layer supported by the first and second partition walls (110-1, 110-2) may be formed on top of the plurality of sub pixel areas. Here, the glass layer may refer to EG. However, the glass layer is not limited thereto, and it can be implemented as various types of materials which can block the inner spaces of the plurality of sub pixel areas from the outer spaces, and through which light emitted from the sub pixel areas can pass.

The fluorescent layer (1000-1) may be formed in an area corresponding to each of the plurality of sub pixel areas on top of the glass layer.

The fluorescent layer (1000-1) is a type of light emitting material, and is a material that absorbs energy and emits light such as red (R), green (G), blue (B) and white (W), and the layer may be quantum dots and the like. When the fluorescent layer (1000-1) is laminated, the characteristic of the sub pixel area is distinguished. For example, when the nanostructure (40) emits light, the emitted light may be converted into any one of R, G, B and W through the fluorescent layer (1000-1).

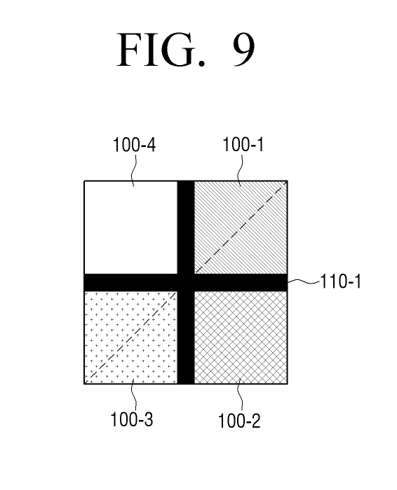

FIG. 9 is a plan view for illustrating a light emitting diode according to an embodiment of the disclosure.

Referring to FIG. 9, the light emitting diode (1000) may include a plurality of sub pixel areas (100-1, 100-2, 100-3, 100-4). According to an embodiment of the disclosure, the plurality of sub pixel areas (100-1, 100-2, 100-3, 100-4) may include fluorescent layers (1000-1) in different colors from one another, and the pixel areas may emit light different from one another. For example, the first sub pixel area (100-1) may be implemented as a red (R) sub pixel, the second sub pixel area (100-2) may be implemented as a green (G) sub pixel, the third sub pixel area (100-3) may be implemented as a blue (B) sub pixel, and the fourth sub pixel area (100-4) may be implemented as a white (W) sub pixel.

Meanwhile, first partition walls (110-1) may be formed between the plurality of sub pixel areas (100-1, 100-2, 100-3, 100-4). The first partition walls (110-1) may prevent transmission of light emitted from a sub pixel area to another sub pixel area.

According to an embodiment of the disclosure, a via hole of a predetermined size may be formed in the center portion of the light emitting diode (1000) contacted by all of the plurality of sub pixel areas (100-1, 100-2, 100-3, 100-4). Also, a metallic substance (80) connecting one side and the other side of the substrate (10) may be formed in the via hole. The metallic substance (80) may provide electrons introduced through the third electrode (100) and the second semiconductor layer (90) to each of the plurality of sub pixel areas (100-1, 100-2, 100-3, 100-4).

Meanwhile, even if each of the plurality of sub pixel areas (100-1, 100-2, 100-3, 100-4) does not include the second semiconductor layer (90) and the third electrode (100), the sub pixels areas may emit light by using electrons introduced through the metallic substance (80) formed in the center portion.

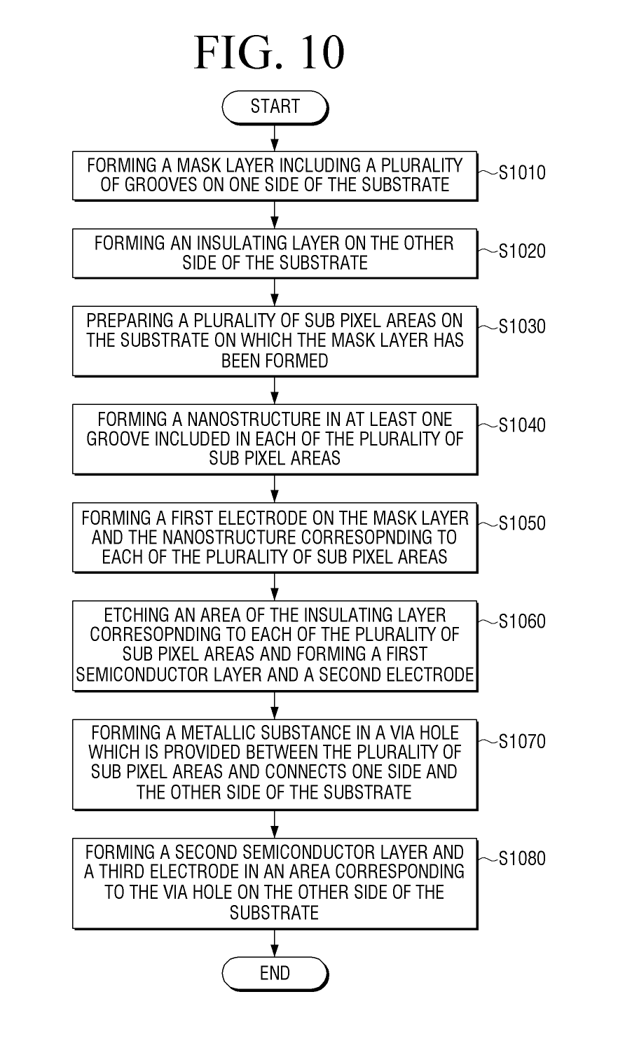

FIG. 10 is a flow chart for illustrating a method of manufacturing a light emitting diode according to an embodiment of the disclosure.

First, a mask layer including a plurality of grooves is formed on one side of the substrate (S1010). Then, an insulating layer is formed on the other side of the substrate (S1020). Next, a plurality of sub pixel areas are provided on the substrate on which the mask layer has been formed (S1030). After that, a nanostructure is formed in at least one groove included in each of the plurality of sub pixel areas (S1040). Then, a first electrode is formed on the mask layer and the nanostructure corresponding to each of the plurality of sub pixel areas (S1050). Next, an area of the insulating layer corresponding to each of the plurality of sub pixel areas is etched, and a first semiconductor layer and a second electrode are formed (S1060). Then, a metallic substance is formed in a via hole which is provided between the plurality of sub pixel areas and connects one side and the other side of the substrate (S1070). Lastly, a second semiconductor layer and a third electrode are formed in an area corresponding to the via hole on the other side of the substrate (S1080).

Here, the nanostructure is a structure where a p-type semiconductor layer, an active layer and an n-type semiconductor layer are laminated, and the first electrode formed on the nanostructure may be an n-type electrode, the first semiconductor layer may be a p-type semiconductor layer, the second electrode may be a p-type electrode, the second semiconductor layer may be an n-type semiconductor layer, and the third electrode may be an n-type electrode.

Meanwhile, in the step S1070 where a metallic substance is formed in the via hole, the metallic substance may be formed such that it contacts the first electrode formed on the mask.

The manufacturing method according to an embodiment of the disclosure includes the step of forming, on the substrate, a first partition wall of a predetermined height in the area of the substrate between the plurality of sub pixel areas. Here, the first partition wall may block transmission of light emitted from at least one nanostructure provided in a sub pixel area among the plurality of sub pixel areas to another sub pixel area.

Also, the manufacturing method includes the step of forming a second partition wall of a predetermined height enclosing the outer rim of the plurality of sub pixel areas, and the second partition wall may block transmission of light emitted from another light emitting diode to the light emitting diode.

Here, the manufacturing method according to an embodiment of the disclosure includes the step of forming a fluorescent layer in a different color in each of the plurality of sub pixel areas, and the fluorescent layer in a different color may convert light emitted from the nanostructure provided in each of the plurality of sub pixel areas into any one of red (R), green (G), blue (B) and white (W).

Here, the step of forming a fluorescent layer may include the step of forming quantum dots inside the plurality of sub pixel areas divided by the first and second partition walls.

In addition, the step of forming a fluorescent layer may include the step of, after forming the quantum dots, forming an encapsulant on top of the quantum dots, and the manufacturing method according to an embodiment of the disclosure may further include the step of forming encapsulation glass (EG) on top of the first and second partition walls and the encapsulant.

Further, the step of forming a fluorescent layer according to an embodiment of the disclosure may include the steps of forming a glass layer supported by the first and second partition walls on top of the plurality of sub pixel areas, and forming a quantum dot layer in an area corresponding to each of the plurality of sub pixel areas on top of the glass layer.

Also, the plurality of sub pixel areas include first to fourth sub pixel areas arranged in the form of a 2*2 matrix, and in the step of forming a metallic substance in the via hole, a via hole of a predetermined size may be formed in the center portion of the plurality of sub pixel areas contacted by all of the first to fourth sub pixel areas.

Meanwhile, the various embodiments of the disclosure described above may be implemented in a recording medium that is readable by a computer or a device similar thereto, by using software, hardware or a combination thereof. In some cases, the embodiments described in this specification may be implemented as a processor itself. According to implementation by software, the embodiments such as procedures and functions described in this specification may be implemented as separate software modules. Each of the software modules may perform one or more functions and operations described in this specification.

Meanwhile, computer instructions for executing the processing operations according to the various embodiments of the disclosure described above may be stored in a non-transitory computer-readable medium. Such computer instructions stored in a non-transitory computer-readable medium may make the processing operations according to the various embodiments described above performed by a specific machine, when they are executed by a processor.

A non-transitory computer-readable medium refers to a medium that stores data semi-permanently, and is readable by machines, but not a medium that stores data for a short moment such as a register, a cache, and memory. As specific examples of a non-transitory computer-readable medium, there may be a CD, a DVD, a hard disc, a blue-ray disc, a USB, a memory card, a ROM and the like.

While the disclosure has been shown and described with reference to preferred embodiments thereof, the disclosure is not limited to the aforementioned specific embodiments, and it is apparent that various modifications can be made by those having ordinary skill in the technical field to which the disclosure belongs, without departing from the gist of the disclosure as claimed by the appended claims. Also, it is intended that such modifications are not to be interpreted independently from the technical idea or prospect of the disclosure.

What is claimed is:

1. A method of manufacturing a light emitting diode comprising:
forming a mask layer including a plurality of grooves on one side of a substrate;
forming an insulating layer on the other side of the substrate;
preparing a plurality of sub pixel areas on the substrate on which the mask layer has been formed;
forming a nanostructure in at least one groove included in each of the plurality of sub pixel areas;
forming a first electrode on the mask layer and the nanostructure corresponding to each of the plurality of sub pixel areas;
etching an area of the insulating layer corresponding to each of the plurality of sub pixel areas and forming a first semiconductor layer and a second electrode;
forming a metallic substance in a via hole which is provided between the plurality of sub pixel areas and connects the one side and the other side of the substrate; and
forming a second semiconductor layer and a third electrode in an area corresponding to the via hole on the other side of the substrate.

2. The method of manufacturing the light emitting diode of claim 1,
wherein the nanostructure is a structure where a p-type semiconductor layer, an active layer and an n-type semiconductor layer are laminated,
wherein the first electrode formed on the nanostructure is an n-type electrode,
wherein the first semiconductor layer is a p-type semiconductor layer, and the second electrode is a p-type electrode, and
wherein the second semiconductor layer is an n-type semiconductor layer, and the third electrode is an n-type electrode.

3. The method of manufacturing the light emitting diode of claim 1,
wherein forming the metallic substance in the via hole comprises
forming the metallic substance such that the metallic substance contacts the first electrode formed on the mask layer.

4. The method of manufacturing the light emitting diode of claim 1, further comprising
forming, on the substrate, a first partition wall of a predetermined height in the area of the substrate between the plurality of sub pixel areas,
wherein the first partition wall blocks transmission of light emitted from at least one nanostructure provided in a sub pixel area among the plurality of sub pixel areas to another sub pixel area.

5. The method of manufacturing the light emitting diode of claim 2, further comprising
forming, on the substrate, a second partition wall of a predetermined height enclosing an outer rim of the plurality of sub pixel areas,
wherein the second partition wall blocks transmission of light emitted from another light emitting diode to the light emitting diode.

6. The method of manufacturing the light emitting diode of claim 5, further comprising
forming a fluorescent layer in a different color in each of the plurality of sub pixel areas,
wherein the fluorescent layer in a different color converts light emitted from the nanostructure provided in each of the plurality of sub pixel areas into any one of red (R), green (G), blue (B) and white (w).

7. The method of manufacturing the light emitting diode of claim 6,
wherein forming the fluorescent layer comprises
forming quantum dots inside the plurality of sub pixel areas divided by the first and second partition walls.

8. The method of manufacturing the light emitting diode of claim 7,
wherein forming the fluorescent layer comprises:
after forming the quantum dots, forming an encapsulant on top of the quantum dots; and
forming encapsulation glass (EG) on top of the first and second partition walls and the encapsulant.

9. The method of manufacturing the light emitting diode of claim 5,
wherein forming the fluorescent layer comprises:
forming a glass layer supported by the first and second partition walls on top of the plurality of sub pixel areas; and
forming a quantum dot layer in an area corresponding to each of the plurality of sub pixel areas on top of the glass layer.

10. The method of manufacturing a light emitting diode of claim 1,
wherein the plurality of sub pixel areas include first to fourth sub pixel areas arranged in the form of a 2*2 matrix, and
wherein forming the metallic substance in the via hole comprises
forming a via hole of a predetermined size in a center portion of the plurality of sub pixel areas contacted by all of the first to fourth sub pixel areas.

11. A light emitting diode comprising:
a substrate;
at least one nanostructure formed in an area of each of a plurality of sub pixel areas provided on one side of the substrate;
a first insulating layer formed in the remaining area on the one side of the substrate;
a first electrode formed on the first insulating layer and the nanostructure;
a first semiconductor layer formed in an area on the other side of the substrate;
a second electrode formed on the first semiconductor layer;
a second insulating layer formed in the remaining area on the other side of the substrate;
a metallic substance which is provided between the plurality of sub pixel areas and connects the one side and the other side of the substrate;
a second semiconductor layer formed in an area corresponding to the metallic substance on the other side of the substrate; and
a third electrode formed on the second semiconductor layer.

12. The light emitting diode of claim 11,
wherein the nanostructure is a structure where a p-type semiconductor layer, an active layer and an n-type semiconductor layer are laminated,
wherein the first electrode formed on the nanostructure is an n-type electrode,
wherein the first semiconductor layer is a p-type semiconductor layer, and the second electrode is a p-type electrode, and
wherein the second semiconductor layer is an n-type semiconductor layer, and the third electrode is an n-type electrode.

13. The light emitting diode of claim 11,
wherein the metallic substance is formed such that the metallic substance contacts the first electrode formed on the first insulating layer.

14. The light emitting diode of claim 11, further comprising
a first partition wall of a predetermined height formed in the area of the substrate between the plurality of sub pixel areas,
wherein the first partition wall blocks transmission of light emitted from at least one nanostructure provided in a sub pixel area among the plurality of sub pixel areas to another sub pixel area.

15. The light emitting diode of claim 12, further comprising
a second partition wall of a predetermined height formed to enclose the outer rim of the plurality of sub pixel areas,
wherein the second partition wall blocks transmission of light emitted from another light emitting diode to the light emitting diode.

16. The light emitting diode of claim 15, further comprising
a fluorescent layer formed in each of the plurality of sub pixel areas,
wherein the fluorescent layer converts light emitted from the nanostructure provided in each of the plurality of sub pixel areas into any one of red (R), green (G), blue (B) and white (w).

17. The light emitting diode of claim 16,
wherein the fluorescent layer is implemented as quantum dots formed inside the plurality of sub pixel areas divided by the first and second partition walls.

18. The light emitting diode of claim 17, further comprising:
an encapsulant formed on top of the quantum dots; and
encapsulation glass (EG) formed on top of the first and second partition walls and the encapsulant.

19. The light emitting diode of claim 15, further comprising
a glass layer supported by the first and second partition walls on top of the plurality of sub pixel areas,
wherein the fluorescent layer is implemented as a quantum dot layer formed in the area corresponding to each of the plurality of sub pixel areas on top of the glass layer.

20. The light emitting diode of claim 11,
wherein the plurality of sub pixel areas include first to fourth sub pixel areas arranged in the form of a 2*2 matrix, and
the metallic substance is formed in a center portion of the plurality of sub pixel areas contacted by all of the first to fourth sub pixel areas.
